(19) United States
(12) Patent Application Publication
(10) Pub. No.: US 2007/0111412 A1
(43) Pub. Date: May 17, 2007

(54) Thin film transistor array panel and method of manufacturing the same

(75) Inventors: Min-Seok Oh, Yongin-si (KR); Jeong-Min Park, Seoul (KR); Sang-Gab Kim, Seoul (KR); Hong-Kee Chin, Suwon-si (KR); Chang-Oh Jeong, Suwon-si (KR); Hong-Sick Park, Suwon-si (KR); Shi-Yul Kim, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/600,481

(22) Filed: Nov. 15, 2006

(30) Foreign Application Priority Data
Nov. 17, 2005 (KR) 10-2005-0110092
Dec. 14, 2005 (KR) 10-2005-0123526

(51) Int. Cl. H01L 21/84

(52) U.S. Cl. 438/158

(57) ABSTRACT

In one embodiment, a thin film transistor array display panel and method of manufacturing the same are provided. A method includes forming a gate line on a substrate; forming a gate insulating layer, a semiconductor layer, and an ohmic contact layer on the gate line; forming a data layer on the ohmic contact layer; forming a photosensitive pattern on the data layer; etching the data layer to form a data line including a source electrode and a drain electrode that is opposite to the source electrode; reflowing the photosensitive pattern to cover side surfaces of the source electrode and the drain electrode; and etching the ohmic contact layer using the reflowed photosensitive pattern as a mask.

### CROSS-REFERENCE TO RELATED APPLICATION

This application claims priority to and the benefit of Korean Patent Application Nos. 10-2005-0110092 and 10-2005-0123526 that were respectively filed in the Korean Intellectual Property Office on Nov. 17, 2005, and Dec. 14, 2006, the entire contents of which are incorporated herein by reference.

### BACKGROUND

(a) Field of the Invention

The present invention relates to a thin film transistor array panel and a manufacturing method thereof.

(b) Description of the Related Art

In general, a flat panel display such as a liquid crystal display (LCD), an organic light emitting diode (OLED) display, and an electrophoretic display includes a plurality of pairs of field generating electrodes and an electro-optical active layer that is interposed therebetween. The LCD includes a liquid crystal layer as an electro-optical active layer, and the OLED display includes an organic emission layer as an electro-optical active layer.

A pair of field generating electrodes is commonly connected to a switching element to receive an electrical signal and the electro-optical active layer converts the electrical signal to an optical signal, thereby displaying an image.

A thin film transistor (TFT), which is a three terminal switching element, is used in the flat panel display. A gate line that transfers a scanning signal for controlling the TFT and a data line that transfers a signal to be applied to a pixel electrode are also provided in the flat display panel (hereinafter, referred to as a “thin film transistor array panel”).

On the other hand, with an increase in an area of a display device such as an LCD or an OLED, gate lines and data lines are lengthened and thus wiring resistance also increases. In order to solve a problem such as signal delay that is caused by an increase in resistance, the gate lines and data lines are required to be made of a material having low resistivity.

However, a material having low resistivity is generally poor in durability and chemical resistance and thus a residual substance may be easily separated by external stimulation or a chemical material. A metal residual substance, that is separated from a source electrode and a drain electrode, for example, may come into contact with other elements, particularly with a semiconductor, and may remain in a channel, thereby affecting thin film transistor characteristics.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to provide a thin film transistor array panel and a manufacturing method thereof having advantages of decreasing contamination due to a metal residual substance, and securing thin film transistor characteristics.

An embodiment of the present invention provides a manufacturing method of a thin film transistor array panel including: forming a gate line on a substrate; forming a gate insulating layer, a semiconductor layer, and an ohmic contact layer on the gate line; forming a data layer on the ohmic contact layer; forming a photosensitive pattern on the data layer; etching the data layer to form a data line including a source electrode and a drain electrode that is opposite to the source electrode; reflowing the photosensitive pattern to cover side surfaces of the source electrode and the drain electrode; and etching the ohmic contact layer using the reflowed photosensitive pattern as a mask.

Another embodiment of the present invention provides a manufacturing method of a thin film transistor array panel including: forming a gate line on a substrate; forming a gate insulating layer, a semiconductor layer, and an ohmic contact layer on the gate line; forming a data layer on the ohmic contact layer; forming a photosensitive pattern including a first portion and a second portion having a thickness smaller than the first portion on the data layer; etching the data layer to form a plurality of data members using the photosensitive pattern as a mask; primarily reflowing the photosensitive pattern; etching the ohmic contact layer and the semiconductor layer using the primarily reflowed photosensitive pattern as a mask; removing the second portion of the photosensitive pattern to expose a part of data members; etching the exposed data members to form a data line including a source electrode and a drain electrode that is opposite to the source electrode; secondarily reflowing the photosensitive pattern to cover side surfaces of the source electrode and the drain electrode; and etching the ohmic contact layer using the secondarily reflowed photosensitive pattern as a mask.

Yet another embodiment of the present invention provides a thin film transistor array panel including: a substrate; first and second signal lines that are insulated on the substrate and intersect each other; a gate electrode that is connected to the first signal; a semiconductor that is overlapped with the gate electrode; a source electrode that is connected to the second signal line; a drain electrode that is disposed apart by a first interval from and is opposite to the source electrode on the semiconductor; a pixel electrode that is connected to the drain electrode; and a pair of ohmic contacts that are formed between the semiconductor and the source electrode and between the semiconductor and the drain electrode and that have a second interval smaller than the first interval and are opposite to each other.

Yet another embodiment of the present invention provides a thin film transistor array panel including: a substrate; first and second signal lines that intersect on the substrate; a gate electrode that is connected to the first signal line; a source electrode that is connected to the second signal line; a drain electrode that is opposite to the source electrode; a pixel electrode that is connected to the drain electrode; a semiconductor that includes an exposed portion between the source electrode and the drain electrode; and an ohmic contact that is formed on the semiconductor and that includes a projection that is not covered with the source electrode and the drain electrode.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 is a layout view of a thin film transistor array panel according to an embodiment of the present invention.

FIGS. 2 and 3 are cross-sectional views of the thin film transistor array panel taken along lines II-II and III-III of FIG. 1, respectively.

FIGS. 4, 21, and 24 are layout views sequentially illustrating a manufacturing method of the thin film transistor array panel according to an embodiment of the present invention.

FIGS. 5 and 6 are cross-sectional views of the thin film transistor array panel taken along lines V-V and VI-VI of FIG. 4, respectively.

FIGS. 7 to 20 are cross-sectional views sequentially illustrating a manufacturing method of the thin film transistor array panel according to an embodiment of the present invention.

FIGS. 22 and 23 are cross-sectional views of the thin film transistor array panel taken along lines XXII-XXII and XXIII-XXIII of FIG. 21, respectively.

FIGS. 25 and 26 are cross-sectional views of the thin film transistor array panel taken along lines XXV-XXV and XXVI-XXVI of FIG. 24, respectively.

### DETAILED DESCRIPTION OF THE EMBODIMENTS

Hereinafter, embodiments of the present invention will be described in detail with reference to the attached drawings such that the present invention can be put into practice by those skilled in the art. As those skilled in the art will realize, the described embodiments may be modified in various different ways, all without departing from the spirit or scope of the present invention.

In the drawings, the thickness of layers, films, panels, regions, etc., may be exaggerated for clarity. Like reference numerals designate like elements throughout the specification. When it is said that any part, such as a layer, film, area, or plate is positioned “on” another part, it means the part is directly on the other part or above the other part with at least one intermediate part. In contrast, when an element is referred to as being “directly on” another element, there are no intervening elements present.

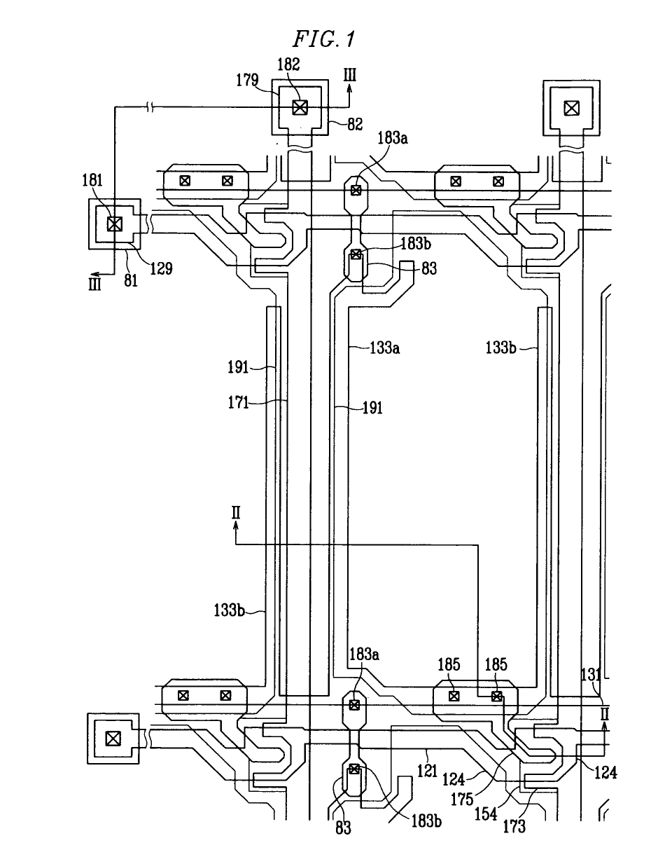

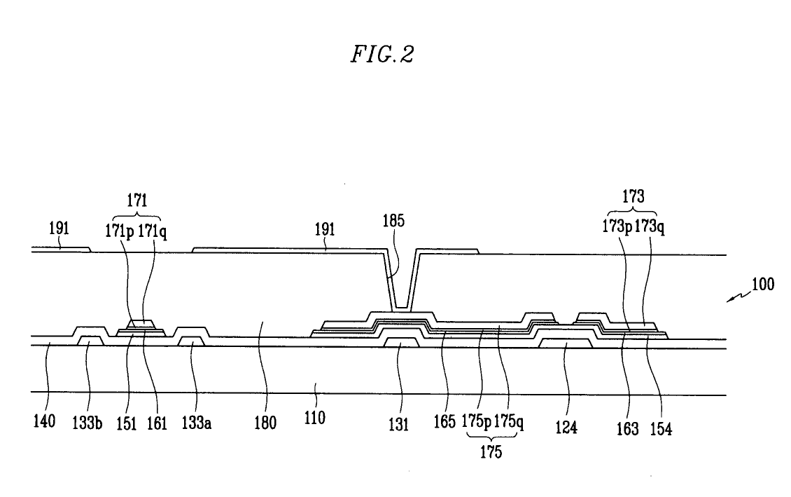

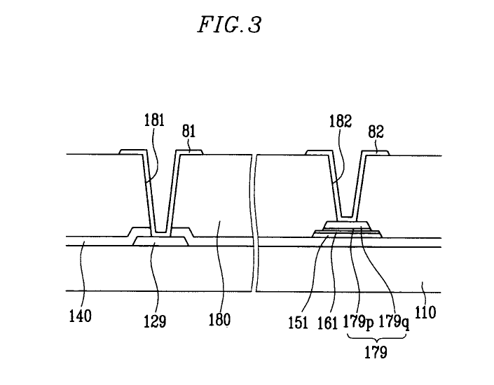

First, a thin film transistor array panel according to an embodiment of the present invention will be described in detail with reference to FIGS. 1 to 3. FIG. 1 is a layout view of a thin film transistor array panel according to an embodiment of the present invention, and FIGS. 2 and 3 are cross-sectional views of the thin film transistor array panel taken along lines II-II and III-III of FIG. 1, respectively.

A plurality of gate lines 121 and a plurality of storage electrode lines 131 are formed on an insulating substrate 110 that is made of transparent glass, plastic, or other applicable insulating material.

The gate lines 121 transfer a gate signal and are mainly extended in a horizontal direction. Each gate line 121 includes a plurality of gate electrodes 124 that protrude downward and a wide end part 129 for connecting to other layers or an external driving circuit. A gate driving circuit (not shown) that generates a gate signal can be mounted on a flexible printed circuit film (not shown) that is attached on the substrate 110, directly mounted on the substrate 110, or integrated in the substrate 110. When the gate driving circuit is integrated on the substrate 110, the gate line 121 is extended to directly connect thereto.

The storage electrode lines 131 receive a predetermined voltage and include a branch line that is extended almost parallel to the gate line 121, and a plurality of pairs of storage electrodes 133a and 133b that are divided therefrom. Each of the storage electrode lines 131 is positioned between two adjacent gate lines 121, and the branch line is positioned proximate to a lower line of two gate lines 121. Each of the storage electrodes 133a and 133b has a fixed end that is connected to the branch line and a free end that is positioned at the opposite side. A fixed end of one side of the storage electrode 133a has a wide area and the free end thereof is divided into a straight portion and a curved portion. However, the shape and disposition of the storage electrode lines 131 can be variously deformed.

The gate lines 121 and the storage electrode lines 131 can be made of a material having low resistivity, for example aluminum containing metals such as aluminum (Al) or an aluminum alloy, silver containing metals such as silver (Ag) or a silver alloy, and copper containing metals such as copper or a copper alloy. The lines may also have a multilayered structure including two conductive layers (not shown) that have different physical properties. One conductive layer may be made of metals having low resistivity, for example aluminum containing metals, silver containing metals, copper containing metals, etc., in order to reduce signal delay or voltage drop. The other conductive layer may be made of excellent materials in terms of physical, chemical, and electrical contact characteristics with other materials, such as indium tin oxide (ITO) and indium zinc oxide (IZO). In one example, the other conductive layer may be made of molybdenum (Mo), chromium (Cr), thallium (Ta), titanium (Ti), etc. Good examples of such a combination may include a molybdenum (alloy) lower layer and a copper (alloy) upper layer, and an aluminum (alloy) lower layer and a molybdenum (alloy) upper layer. However, the gate lines 121 and the storage electrode lines 131 may be made of various other metals or conductors.

Side surfaces of the gate lines 121 and the storage electrode lines 131 are inclined to a surface of the substrate 110, and an inclination angle thereof is from about 30° to about 80° in one example.

A gate insulating layer 140, which is made of silicon nitride SiNₓ, silicon oxide SiO₂, or so on, in one example, is formed on the gate lines 121 and the storage electrode lines 131.

A plurality of semiconductor stripes 151 that are made of hydrogenated amorphous silicon (a-Si is an abbreviation for amorphous silicon), etc., are formed on the gate insulating layer 140. Each semiconductor stripe 151 includes a plurality of projections 154 that are mainly extended in a vertical direction and that are extended toward the gate electrode 124. The semiconductor stripe 151 has a wide width around the gate line 121 and the storage electrode line 131 to widely cover them. A plurality of ohmic contact stripes and islands 161 and 165 are formed on the semiconductor stripe 151. The ohmic contacts 161 and 165 may be made of a material such as n+ hydrogenated amorphous silicon (in which n-type impurities such as phosphorus (p) are doped with a high concentration) or silicide. Each ohmic contact stripe 161 has a plurality of projections 163, and the projections 163 and the ohmic contact island 165 are formed in pairs and disposed on the projections 154 of the semiconductor stripes 151. Side surfaces of the semiconductor stripes 151 and the ohmic contacts 161 and 165 are also inclined to a surface of the substrate 110, and an inclination angle thereof is from about 30° to about 80° in one example.

A plurality of data lines 171 and a plurality of drain electrodes 175 are formed on the ohmic contacts 161 and 165.

The data lines 171 transfer data signals and are mainly extended in a vertical direction to intersect the gate lines 121. Each data line 171 also intersects a storage electrode line 131 and is formed between sets of adjacent storage electrodes 133a and 133b

Each data line 171 includes a plurality of source electrodes 173 that are extended toward the gate electrode 124 and a wide end portion 179 for connecting with other layers or an external driving circuit. A data driving circuit (not shown) that generates a data signal may be mounted on a flexible printed circuit film (not shown) that is attached to the substrate 110, directly mounted on the substrate 110, or integrated in the substrate 110. When the data driving circuit is integrated in the substrate 110, the data line 171 is extended to directly connect thereto.

Each drain electrode 175 is separated from the data line 171 and faces the source electrode 173 on the projection 154 of the semiconductor stripe 151. Each drain electrode 175 has one end part having a wide area and the other end part having a bar-shape. The wide end part is overlapped with the storage electrode line 131 and the bar-shaped end part is partly surrounded with the curved source electrode 173.

The projections 154 of the semiconductor stripes 151, the projections 163 of the ohmic contacts 161, and the ohmic contact islands 165 are exposed between the source electrodes 173 and the drain electrodes 175.

The semiconductor stripes 151 and the ohmic contacts 161 and 165 are formed in lower parts of the data lines 171 and the drain electrodes 175, and they have substantially the same plane shape except at a portion between the source electrodes 173 and the drain electrodes 175. However, because the semiconductor stripes 151 and the ohmic contacts 161 and 165 have a larger width than the data lines 171 and the drain electrodes 175, end parts of each semiconductor stripe 151 and the ohmic contacts 161 and 165 are exposed without being covered by the data lines 171 and the drain electrodes 175.

One gate electrode 124, one source electrode 173, one drain electrode 175, and the projection 154 of the semiconductor stripe 151 constitute one TFT, and a channel of the TFT is formed in the projection 154 between the source electrode 173 and the drain electrode 175. The data lines 171 and the drain electrodes 175 include a lower layer and an upper layer in one example. The lower layer may be made of a conductor having excellent adhesion such as an Mo containing metal, and the upper layer may be made of a conductor having a low resistivity such as a Cu containing metal, Al containing metal, and Ag containing metal. The thickness of the lower layer is from about 200 Å to about 1000 Å in one example, and the thickness of the upper layer is from about 1500 Å to about 3000 Å in one example.

In FIGS. 2 and 3, with respect to the drain electrode 175 and the data line 171 including the source electrode 173 and the end portion 179, a character p is added to reference numerals in the lower layer, and a character q is added to reference numerals in the upper layer. Side surfaces of the data line 171 and the drain electrode 175 also are inclined to a surface of the substrate 110, and an inclination angle thereof is from about 30° to about 80° in one example.

The ohmic contacts 161 and 165 exist between the semiconductor stripe 151 and the data line 171 and drain electrode 175 to lower contact resistance therebetween, and include a portion that is partly protruded between the source electrode 173 and the drain electrode 175.

The passivation layer 180 is formed on the data line 171, the drain electrode 175, and the exposed portion of the projection 154. The passivation layer 180 is made of an inorganic insulator such as SiNx or SiO₂, an organic insulator, a low dielectric constant insulator, and so on, in one example. The organic insulator and the low dielectric constant insulator have a dielectric constant of 4.0 or less, in one example, and the low dielectric constant insulator includes, for example, a-Si:C:O or a-Si:O:F that are formed by a deposition process, such as plasma enhanced chemical vapor deposition (PECVD). The passivation layer 180 may be made of an organic insulator having photosensitivity, and a surface thereof may be flat. However, the passivation layer 180 can have a double-layered structure of a lower inorganic layer and an upper organic layer in order to prevent damage to the exposed portion of the projection 154 while having excellent insulating characteristics of the organic layer.

A plurality of contact holes 182 and 185 for exposing each of the end portions 179 of the data line 171 and the drain electrode 175 are formed in the passivation layer 180, and a plurality of contact holes 181 for exposing the end portion 129 of the gate line 121 and a plurality of contact holes 183a and 183b for exposing around a fixed end of the storage electrodes 133a and 133b or some of the storage electrode line 131 of the free end thereof are formed in the passivation layer 180 and the gate insulating layer 140.

A plurality of pixel electrodes 191, a plurality of overpasses 83, and a plurality of contact assistants 81 and 82 are formed on the passivation layer 180. They may be made of a transparent conductive material such as ITO or IZO, or a reflective metal such as Al, Ag, or alloys thereof.

The pixel electrodes 191 are physically and electrically connected to the drain electrodes 175 through the contact holes 185 to receive a data voltage from the drain electrodes 175. A pixel electrode 191 to which a data voltage is applied and a common electrode (not shown) of another display panel (not shown) that receives a common voltage generate an electric field, thereby determining a direction of liquid crystal molecules of a liquid crystal layer (not shown) between the two electrodes. The pixel electrode 191 and the common electrode constitute a capacitor (hereinafter referred to as a “liquid crystal capacitor”), and maintain an applied voltage even after the TFT is turned off.

The pixel electrodes 191 are overlapped with the storage electrodes 133a and 133b and the storage electrode lines 131. A capacitor that is formed as a pixel electrode 191 and a drain electrode 171 that is electrically connected thereto and overlapped with a storage electrode line 131 is called a storage capacitor, and the storage capacitor enhances voltage sustainability of a liquid crystal capacitor.

The contact assistants 81 and 82 are connected to the end portion 129 of the gate line 121 and the end portion 179 of the data line 171 through contact holes 181 and 182, respectively. The contact assistants 81 and 82 enhance adhesion between the respective end portions 179 and 129 of the data line 171 and the gate line 121 and an external apparatus and protect them.

Each overpass 83 crosses a gate line 121 and is connected to an exposed portion of a storage electrode line 131 and an exposed end part of a free end of a storage electrode 133b through a pair of contact holes 183a and 183b that are opposite to each other with the gate line 121 interposed therebetween. The storage electrodes 133a and 133b and the storage electrode lines 131 along with the overpasses 83 can be used to repair defects of the gate lines 121, the data lines 171, or the TFTs.

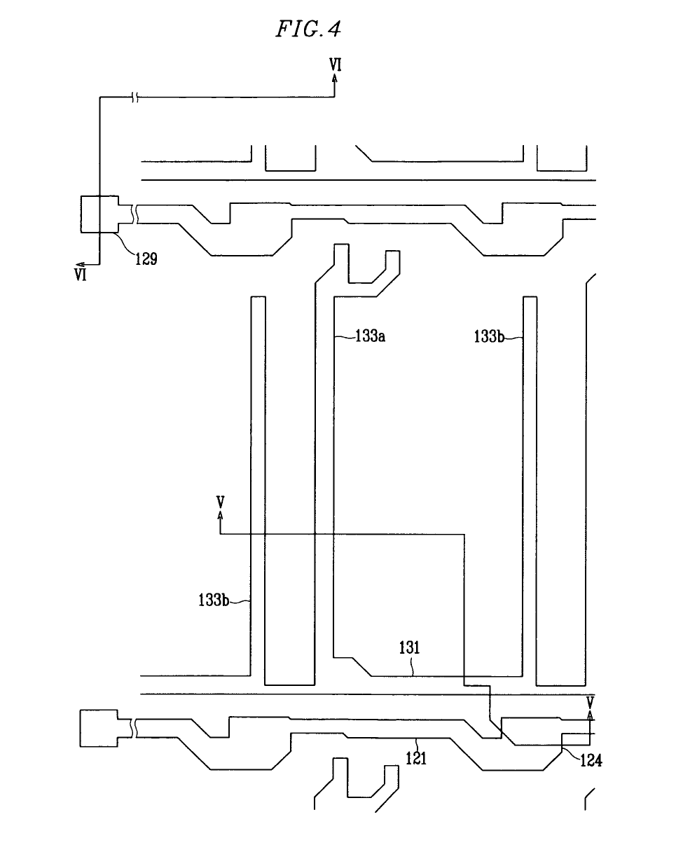

Now, a method of manufacturing the thin film transistor array panel shown in FIGS. 1 to 3 will be described in detail with reference to FIGS. 4 to 26.

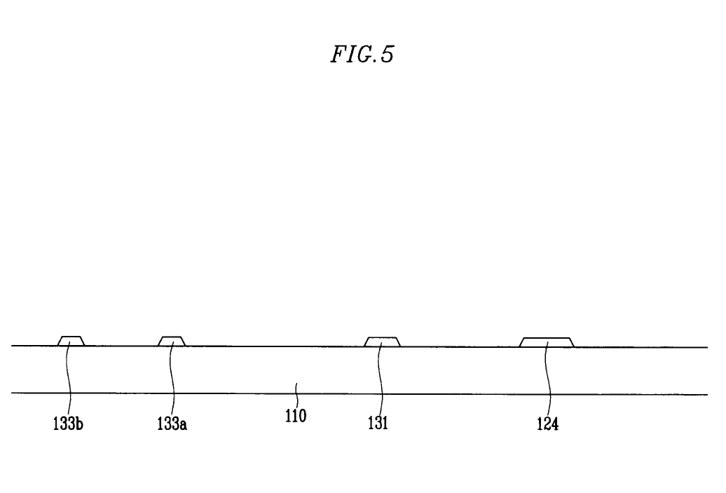

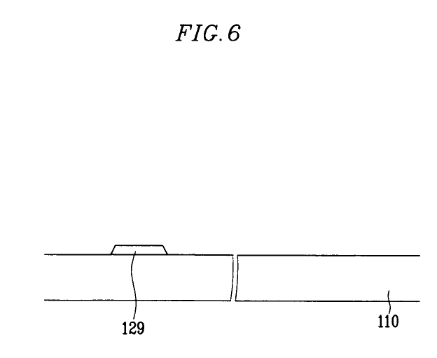

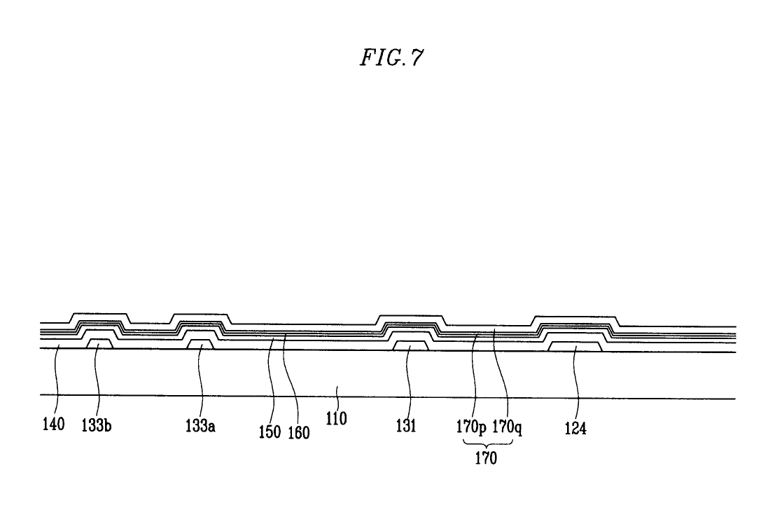

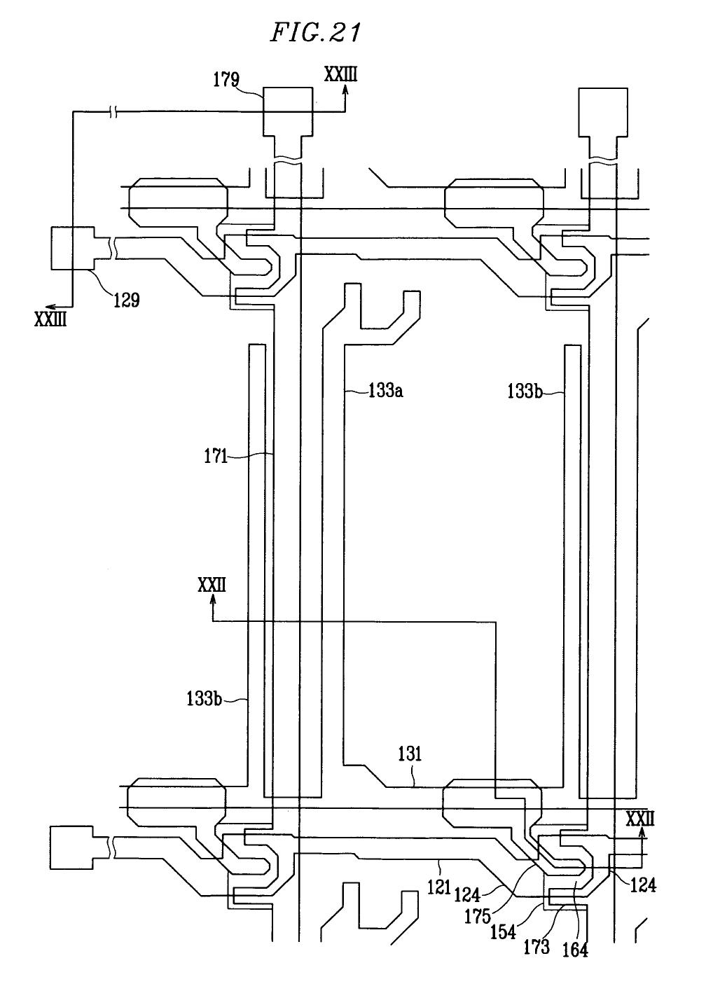

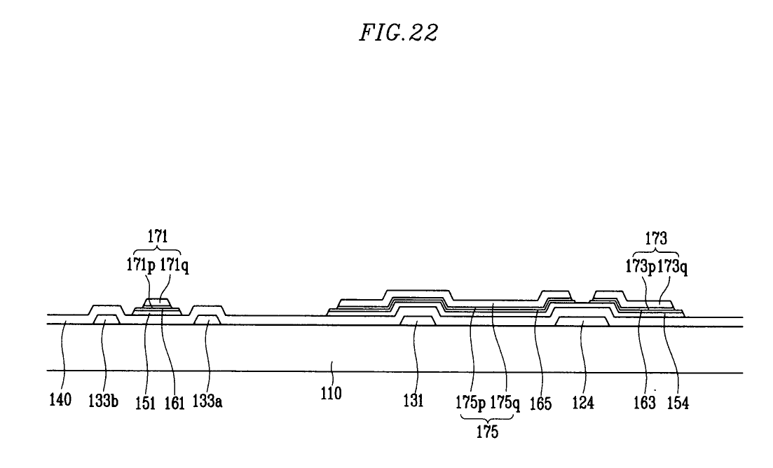

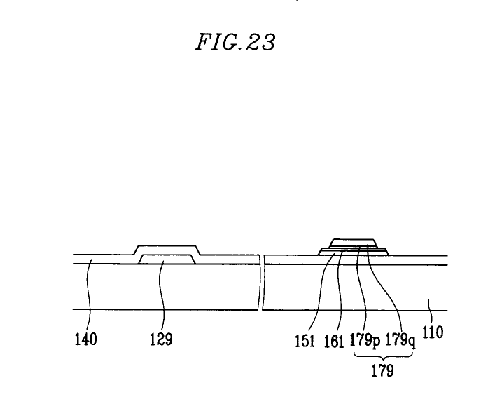

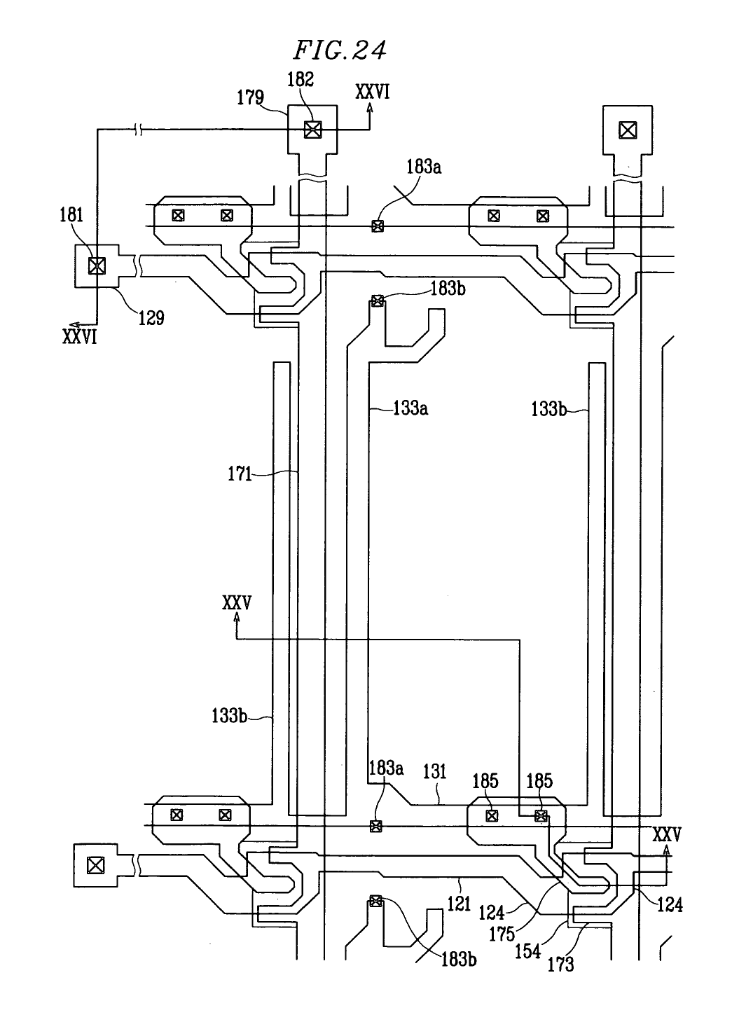

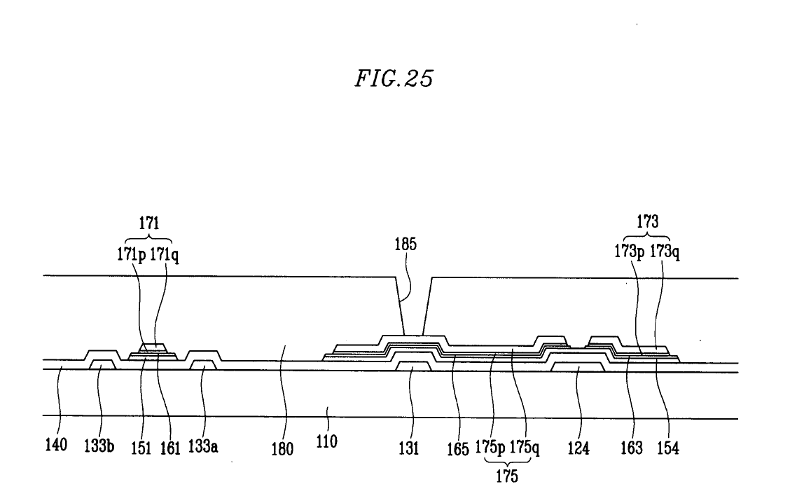

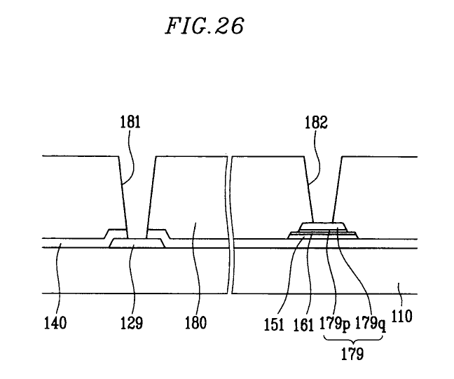

FIGS. 4, 21, and 24 are layout views sequentially illustrating a manufacturing method of the thin film transistor array panel according to an embodiment of the present invention, FIGS. 5 and 6 are cross-sectional views of the thin film transistor array panel taken along lines V-V and VI-VI of FIG. 4, respectively, and FIGS. 7 to 20 are cross-sectional views sequentially illustrating a manufacturing method of the thin film transistor array panel according to an embodiment of the present invention. FIGS. 22 and 23 are cross-sectional views of the thin film transistor array panel taken along lines XXII-XXII and XXIII-XXIII of FIG. 21, respectively, and FIGS. 25 and 26 are cross-sectional views of the thin film transistor array panel taken along lines XXV-XXV and XXVI-XXVI of FIG. 24, respectively.

First, as shown in FIGS. 4 to 6, after a conductive layer including Cu, in one example, is deposited on the insulating substrate 110 that is made of transparent glass, plastic, or so on, a plurality of gate lines 121 including the gate electrode 124 and the end portion 129 and a plurality of storage electrodes lines 131 including the storage electrodes 133a and 133b are formed by performing wet etching.

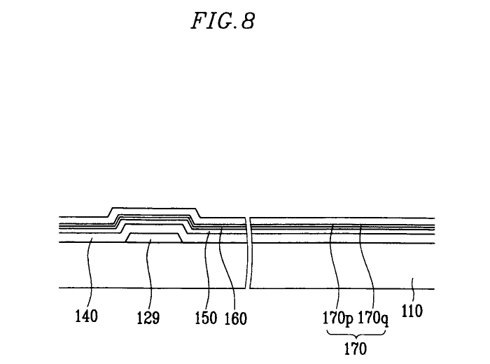

Next, as shown in FIGS. 7 and 8, a gate insulating layer 140 that is made of silicon nitride (SiNx) and so on, an intrinsic amorphous silicon (a-Si) layer 150 in which impurities are not doped, and an extrinsic amorphous silicon (n+ a-Si) layer 160 in which impurities are doped, are sequentially deposited on the gate line 121 and the storage electrode line 131 by a plasma enhanced chemical vapor deposition (PECVD) method in one example. The intrinsic a-Si layer 150 may be made of hydrogenated amorphous silicon, etc., and the extrinsic a-Si layer 160 may be made of n+ hydrogenated a-Si heavily doped with an n-type impurity such as phosphorous P, or silicide.

Next, a data layer 170 including a lower conductive layer 170p that is made of molybdenum nitride (MoN) and an upper conductive layer 170q that is made of Cu is formed on the extrinsic a-Si layer 160. The lower conductive layer 170p and the upper conductive layer 170q are formed by sputtering, and the lower conductive layer 170p may be formed while supplying a nitrogen-containing gas such as nitrogen gas (N₂) when depositing Mo. The MoN can prevent Cu from diffusing to Mo.

Next, a photosensitive film is formed on the data layer 170. The photosensitive film may be made of photosensitive composition having low thermal resistance and an excellent flow property. A photosensitive composition that can be applied to the present embodiment includes an alkali soluble resin and a photosensitive compound having a ballast structure.

Novolac resin is a representative alkali soluble resin. The novolac resin is basically a polymer that is obtained by reacting a phenol monomer and an aldehyde compound in the presence of an acid catalyst. A phenol monomer that can be used in one example is obtained by synthesizing meta (m)-cresol and para (p)-cresol in a specific ratio. An aldehyde compound that can be used in one example is obtained by mixing one or more selected from formaldehyde, p-formaldehyde, benzaldehyde, nitrobenzaldehyde, acetaldehyde, etc. Furthermore, an acidic catalyst that is added when the phenol monomer and the aldehyde compound are reacted can be selected from, for example, hydrochloric acid, nitric acid, sulfuric acid, formic acid, oxalic acid, and so on.

The weight average molecular weight (MW) of a novolac resin that is suitable for applying to the present embodiment is about 2000 to 5000. When the weight average molecular weight is lower than 2000, it is difficult to form a micro pattern due to low sensitivity, and when it exceeds 5000, reflow characteristics of the photosensitive film become poor and adhesion with other films becomes weak. It is preferable that the alkali soluble resin is present at about 5 wt % to about 30 wt % of the total content of the photosensitive composition.

A photosensitive compound is a compound that generates photochemical reaction by reacting with light. In the present embodiment, a compound having a ballast structure of Chemical Formula (I) is used as a photosensitive compound that can increase fluidity of a photosensitive film with a photochemical reaction. 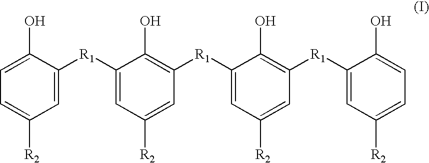
(where R₁ and R₂ are alkyl groups and R₁ and R₂ may be the same as or different from each other).

As can be seen in the formula, the ballast structure can confer flexibility to a compound and increase fluidity of a photosensitive composition because an alkyl group is connected between each pair of a plurality of benzene rings.

Furthermore, the ballast structure can show photosensitive characteristics because a diazide compound such as quinone diazide is combined with a hydroxy group (—OH) of the ballast structure.

Compounds in which the diazide compound is combined with the ballast structure include, for example, 2,2′-methylene bis [6-[(2-hydroxy-5-methyl phenyl)methyl]-4-methyl-1,2-naphtoquinonediazide-5-sulfonate].

The photosensitive compound can be present at about 2 wt % to about 10 wt % of the total content of the photosensitive composition. When a photosensitive compound is present at less than 2 wt %, the response speed is deteriorated at exposure, and when it has a content of more than 10 wt %, the response speed abruptly increases and thus it is not formed with a good profile.

Furthermore, in order to reduce thermal resistance of a photosensitive film, the present invention can include a thermal resistance adjusting additive. The thermal resistance adjusting additive is a compound that can reflow at a temperature lower than an original reflow temperature by reducing thermal resistance of the photosensitive composition. The thermal resistance adjusting additive includes a first bisphenol compound that is expressed by Chemical Formula (II) 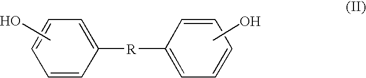
(where R is a methyl group, an ethyl group, or a propyl group), or a second bisphenol compound that is expressed by Chemical Formula (III) 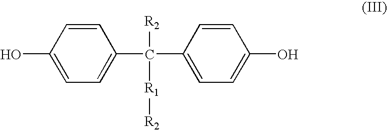
(where R₁ is a methyl group, an ethyl group, a propyl group, a butyl group, a pentyl group, or a hexyl group, and R₂ is hydrogen or a methyl group). The thermal resistance adjusting additive can be present at about 0.5 wt % to about 3 wt % of the total content of the photosensitive composition.

The photosensitive composition may further include plasticizers, stabilizers, or surfactants as needed in addition to the other ingredients.

An alkali soluble resin, a photosensitive compound, and various additives are used in solution form that is dissolved by an organic solvent. The organic solvent can be selected from, for example, ethyl acetate, butyl acetate, diethylene glycol dimethyl ether, diethylene glycol dimethyl ethyl ether, methyl methoxy propionate, ethyl ethoxy propionate, ethyl lactate, propylene glycol methyl ether acetate, propylene glycol methyl ether acetate, propylene glycol propyl ether acetate, methyl cellosolve acetate, ethyl cellosolve acetate, diethylene glycol methyl acetate, diethylene glycol ethyl acetate, acetone, methyl isobutyl ketone, cyclohexanone, dimethyl formamide, N,N-dimethyl acetamide, N-methyl-2-pyrolidone, γ-butyrolactone, diethyl ether, ethylene glycol dimethyl ether, diglyme, tetrahydrofurane, methanol, ethanol, propanol, isopropanol, methyl cellosolve, ethyl cellosolve, diethylene glycol methyl ether, diethylene glycol ethyl ether, dipropylene glycol methyl ether, toluene, xylene, hexane, heptane, octane, etc.

The solvent may be contained as a residual quantity given that the alkali soluble resin, the photosensitive compound, and the various additives in the total content of photosensitive composition preferably are present at about 60 wt % to about 90 wt %.

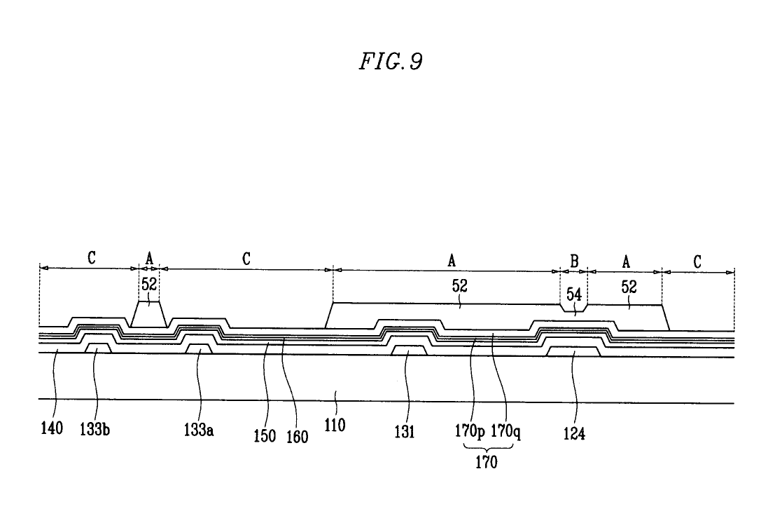

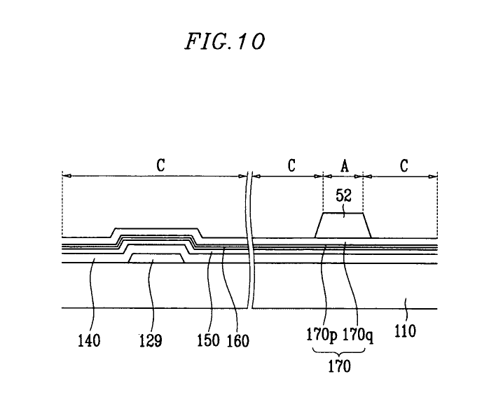

Next, as shown in FIGS. 9 and 10, a first photosensitive pattern 52 and a second photosensitive pattern 54 that has a smaller thickness than the first photosensitive pattern 52 are formed by exposing and developing a photosensitive film that is made of the above-described photosensitive composition.

After the photosensitive film is developed, heat treatment (post bake) is not performed or heat treatment is performed at a temperature lower than a reflow temperature of the photosensitive film. In general, heat treatment that is performed at this step is performed in order to firmly fix the photosensitive patterns that are patterned by a developer on a substrate. However, as described above, when heat treatment of the photosensitive patterns having low thermal resistance is performed at a high temperature, reflow of the photosensitive patterns are caused and thus a profile of photosensitive patterns that are formed at an initial stage is destroyed. If that occurs, an inclination angle and a profile of the photosensitive patterns that are formed in a channel region change, whereby subsequent etching becomes poor, and in some cases the thin film transistor characteristics may be affected and a short circuit may occur.

Accordingly, after the photosensitive film is developed, and heat treatment is not performed or after heat treatment is performed at a temperature lower than a reflow temperature of the photosensitive composition, an etching stage is immediately performed.

Here, for convenience of description, the intrinsic a-Si layer 150, the extrinsic a-Si layer 160, and the data layer 170 include first portions A, second portions B, and third portions C. The first portions A are located on wire areas, the second portions B are located on channel areas, and the third portions C are located on the remaining areas.

The first photosensitive patterns 52 that are positioned in the first portion A among the photosensitive patterns 52 and 54 has a larger thickness than that of the second photosensitive pattern 54 that is positioned in the second portion B, and the third portion C of the photosensitive film is entirely removed. At this time, a ratio between a thickness of the first photosensitive pattern 52 and a thickness of the second photosensitive pattern 54 may be changed depending on process conditions at an etching process to be described later, but it is preferable that a thickness of the second photosensitive pattern 54 becomes half or less of that of the first photosensitive pattern 52.

There are several methods of forming different thicknesses of the photosensitive film depending on position, and the methods include, for example, a method of providing a transparent area, a light blocking area, and a semi-transparent area in an exposure mask. In the semi-transparent area, a thin film having a slit pattern, a lattice pattern, middle transmittance, or a middle thickness is provided. When the slit pattern is used, it is preferable that a width of the slits or an interval between slits is smaller than the resolution of an exposer that is used in a photolithography process.

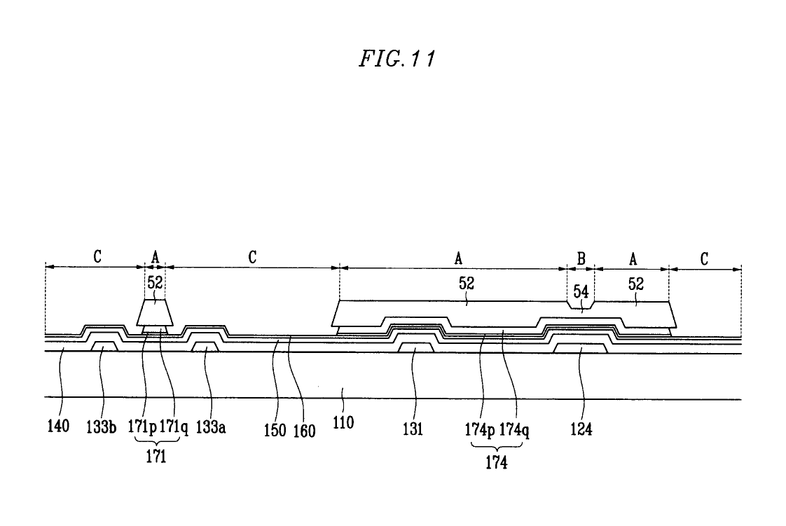

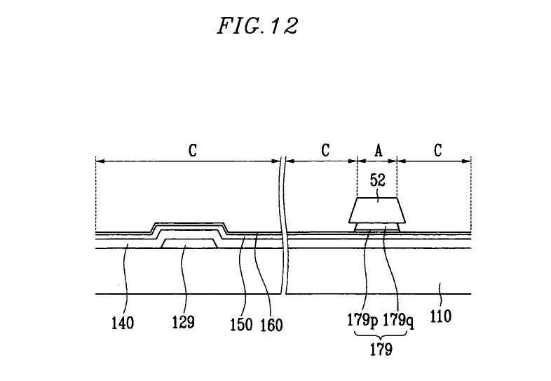

Next, as shown in FIGS. 11 and 12, a plurality of data patterns 171, 174, and 179 are formed by removing the data layer 170 that is exposed in the third portion C using the first photosensitive pattern 52, by wet etching.

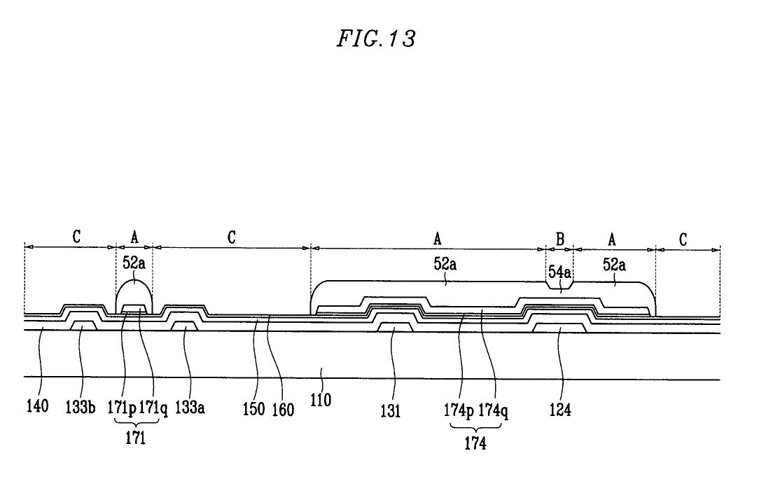

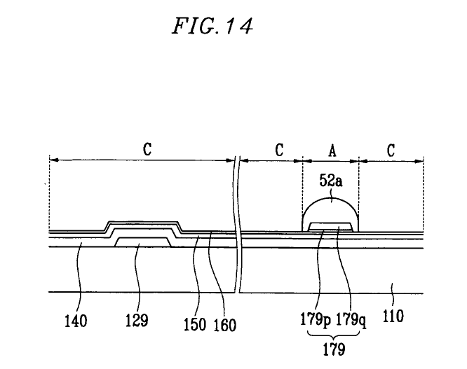

Next, as shown in FIGS. 13 and 14, the first reflow is performed by performing heat treatment of the photosensitive patterns 52 and 54 at a temperature of about 130° C. to 160° C.

Because the above-described photosensitive composition includes a photosensitive compound and a thermal resistance adjusting additive having a ballast structure, it can be easily reflowed in the temperature range. At this time, the reflowed photosensitive patterns 52a and 54a completely cover the data patterns 171, 174, and 179.

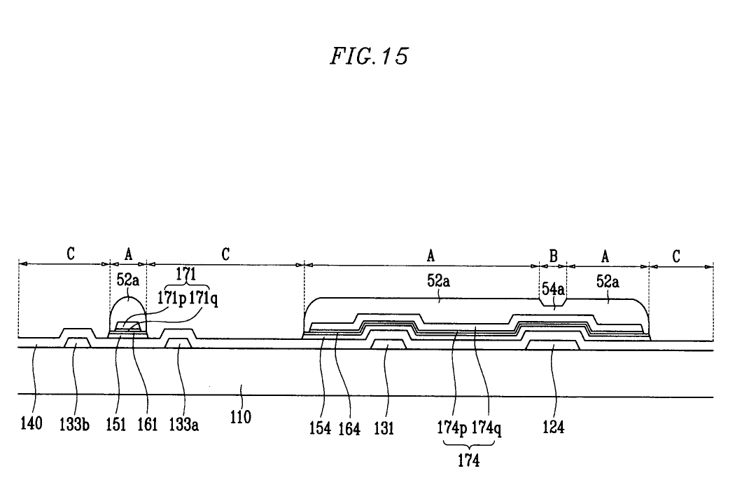

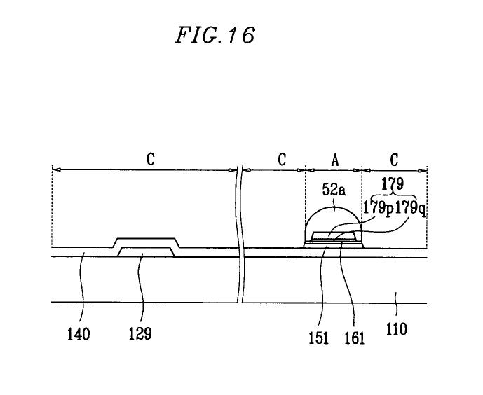

Next, as shown in FIGS. 15 and 16, the semiconductor stripe 151 including the projection 154 and the extrinsic a-Si pattern 164 are formed by performing dry etching of the extrinsic a-Si layer 160 and the intrinsic a-Si layer 150, which remain in the third portion C, using the reflowed photosensitive patterns 52a and 54a as a mask.

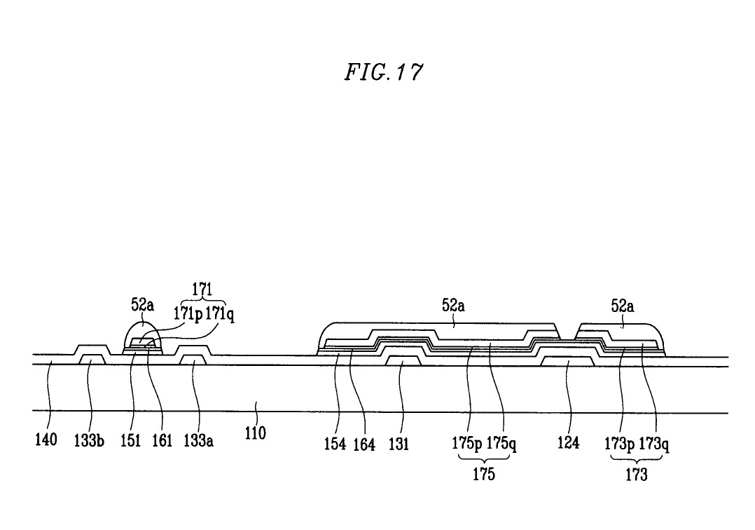

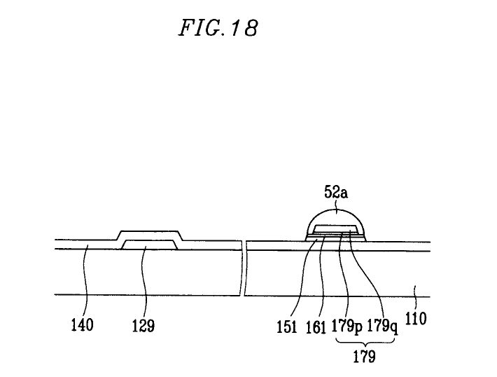

Next, as shown in FIGS. 17 and 18, the reflowed second photosensitive pattern 54a is removed using an etch back process. At this time, because the reflowed first photosensitive pattern 52a is also removed by a thickness of the second photosensitive pattern 54a, it becomes thinner. Furthermore, because a side surface of the reflowed first photosensitive pattern 52a is also somewhat removed, both ends of data patterns 171, 174, and 179 that are formed in the lower part are exposed.

Next, the data pattern 174 is divided into the source electrode 173 and the drain electrode 175 by etching the data pattern 174 using the reflowed first photosensitive pattern 52a as a mask, and the extrinsic a-Si pattern 164 is exposed in a channel region between the source electrode 173 and the drain electrode 175.

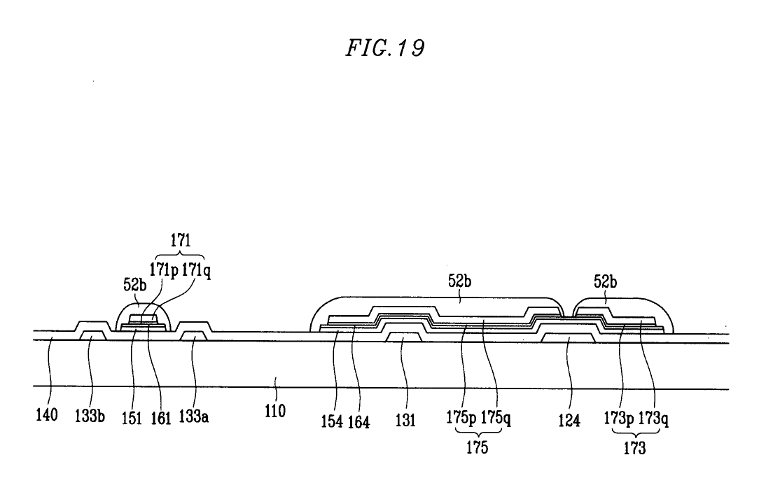

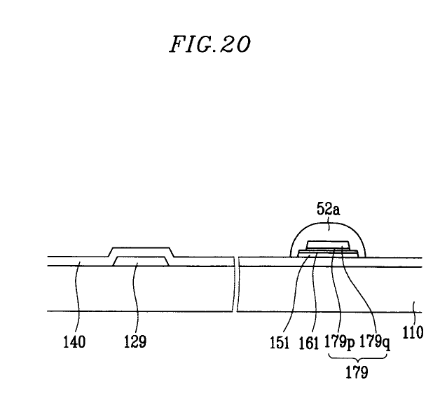

Next, as shown in FIGS. 19 and 20, the secondary reflow is performed by performing heat treatment of the reflowed first photosensitive pattern 52a at a temperature of about 130 to 160° C. The reflowed first photosensitive pattern 52b completely covers both ends of the data line 171 and the drain electrode 175 including the source electrode 173. Particularly, a metal having low durability and low chemical resistance like Cu is not exposed by completely covering side surfaces of the source electrode 173 and the drain electrode 175 that are opposite to each other about the channel region.

Next, as shown in FIGS. 17 to 19, dry etching of an exposed portion of the extrinsic a-Si pattern 164 is performed. At this time, dry etching is performed using a chlorine-containing gas such as Cl₂, HCl, BCl₃, CCl₄, and SiCl₂H₂.

By completely covering side surfaces of the source electrode 173 and the drain electrode 175 through reflowing the photosensitive pattern having low thermal resistance, it is possible to prevent a part of Cu from dropping on the semiconductor layer due to damage of Cu constituting the source electrode 173 and the drain electrode 175 when the extrinsic a-Si pattern 164 is etched. Furthermore, it is possible to prevent Cu from corroding by the chlorine-containing gas that is supplied when the extrinsic a-Si pattern 164 is etched. Therefore, by covering side surfaces of the source electrode and the drain electrode through the reflow of the photosensitive pattern even when low resistance wiring such as Cu is used, it is possible to prevent physical and chemical damage during subsequent processes. Accordingly, it is possible to reduce factors that affect the thin film transistor characteristics such as leakage current increase by preventing a metal residual substance from remaining on the semiconductor layer.

Next, the reflowed first photosensitive pattern 52b is removed using a stripper. Removal is performed in one example by spraying a stripper on the reflowed first photosensitive pattern 52b for about 60 to 300 seconds at a temperature of about 50 to 80° C. Next, as shown in FIGS. 20 to 22, the passivation layer 180 is formed to cover the projection 154 of the semiconductor stripe 151 that is covered by the data line 171 and the drain electrode 175.

Next, a plurality of contact holes 181, 182, 183a, 183b, and 185 are formed by etching the passivation layer 180 with a photolithography process.

Finally, as shown in FIGS. 1 to 3, the pixel electrodes 191, the contact assistants 81 and 82, and the overpasses 83 are formed by depositing a transparent conductive material such as ITO or IZO on the passivation layer 180 (e.g., by sputtering) and then patterning the deposited material.

As described above, it is possible to prevent low resistivity wiring from receiving physical and chemical damage during subsequent processes by covering low resistivity wiring through reflowing a photosensitive film having low thermal resistance, so that it is possible to reduce factors that affect thin film transistor characteristics such as a leakage current increase.

While this invention has been described in connection with several embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a thin film transistor array panel, comprising:
forming a gate line on a substrate;
forming a gate insulating layer, a semiconductor layer, and an ohmic contact layer on the gate line;
forming a data layer on the ohmic contact layer;
forming a photosensitive pattern on the data layer;
etching the data layer to form a data line including a source electrode and a drain electrode that is opposite to the source electrode;
reflowing the photosensitive pattern to cover side surfaces of the source electrode and the drain electrode; and
etching the ohmic contact layer using the reflowed photosensitive pattern as a mask.

2. The method of claim 1, wherein the data layer comprises at least one of copper or a copper alloy, aluminum or an aluminum alloy, and silver or a silver alloy.

3. The method of claim 1, wherein the reflowing of the photosensitive pattern is performed at a temperature from about 130° C. to about 160° C.

4. The method of claim 1, wherein the forming of the photosensitive pattern is performed at a lower temperature than a temperature that reflows the photosensitive pattern.

5. The method of claim 1, wherein the forming of the photosensitive pattern comprises:
coating a photosensitive film;
exposing the photosensitive film; and
developing the exposed photosensitive film,
wherein heat treatment is not performed between the developing of the exposed photosensitive film and the forming of the data line and the drain electrode.

6. The method of claim 1, wherein the etching of the ohmic contact layer comprises supplying a chlorine-containing gas.

7. The method of claim 1, wherein the photosensitive pattern comprises an alkali soluble resin; and
a photosensitive compound having a ballast structure of Chemical Formula (I) 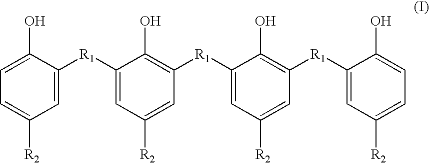
wherein R₁ and R₂ are alkyl groups and R₁ and R₂ may be the same as or different from each other.

8. The method of claim 7, wherein the photosensitive compound comprises a diazide compound.

9. The method of claim 7, wherein the photosensitive compound comprises 2,2′-methylene bis[6-[(2-hydroxy-5-methyl phenyl)methyl]-4-methyl-1,2-naphtoquinonediazide-5-sulfonate].

10. The method of claim 7, wherein the photosensitive pattern further comprises a thermal resistance adjusting additive.

11. The method of claim 10, wherein the thermal resistance adjusting additive includes at least one of a first compound of Chemical Formula (II) 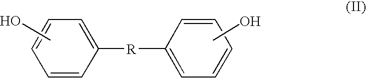
wherein R is a methyl group, an ethyl group, or a propyl group, and
a second compound of Chemical Formula (III) 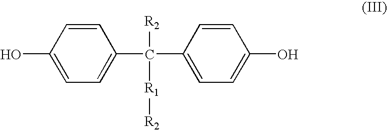
wherein R₁ is a methyl group, an ethyl group, a propyl group, a butyl group, a pentyl group, or a hexyl group, and R₂ is hydrogen (H) or a methyl group.

12. The manufacturing method of claim 10, wherein the thermal resistance adjusting additive has an average molecular weight of about 200 to about 400.

13. The method of claim 7, wherein the photosensitive pattern comprises about 5 wt % to about 30 wt % of an alkali soluble resin, about 2 wt % to about 10 wt % of a photosensitive compound, about 0.5 wt % to about 3 wt % of a thermal resistance adjusting additive, and a residual quantity of solvent.

14. The method of claim 7, wherein the alkali soluble resin comprises a novolac resin including m-cresol and p-cresol, and an average molecular weight of the novolac resin is about 2000 to 5000.

15. The method of claim 1, wherein the forming of the photosensitive pattern comprises forming a first portion and a second portion having a smaller thickness than the first portion.

16. The method of claim 15, further comprising, after the forming of the photosensitive pattern:
etching the data layer using the photosensitive pattern as a mask;
etching the semiconductor layer using the etched data layer as a mask; and
removing a predetermined thickness of the photosensitive pattern.

17. The method of claim 15, wherein the forming of the data layer comprises forming a first data layer including Mo and forming a second data layer including Cu.

18. The method of claim 17, wherein the forming of the first data layer includes supplying a nitrogen-containing gas.

19. A method of manufacturing a thin film transistor array panel, comprising:
forming a gate line on a substrate;
forming a gate insulating layer, a semiconductor layer, and an ohmic contact layer on the gate line;
forming a data layer on the ohmic contact layer;
forming a photosensitive pattern including a first portion and a second portion having a smaller thickness than the first portion on the data layer;
etching the data layer to form a plurality of data members using the photosensitive pattern as a mask;
primarily reflowing the photosensitive pattern;
etching the ohmic contact layer and the semiconductor layer using the reflowed photosensitive pattern as a mask;
removing the second portion of the photosensitive pattern to expose a part of the data members;
etching the exposed data members to form a data line including a source electrode and a drain electrode that is opposite to the source electrode;
secondarily reflowing the photosensitive pattern to cover side surfaces of the source electrode and the drain electrode; and
etching the ohmic contact layer using the secondarily reflowed photosensitive pattern as a mask.

20. A thin film transistor array panel, comprising:
a substrate;
first and second signal lines that intersect on the substrate;
a gate electrode that is connected to the first signal line;
a semiconductor that is overlapped with the gate electrode;
a source electrode that is connected to the second signal line;
a drain electrode that is disposed apart by a first interval from and opposite to the source electrode on the semiconductor;
a pixel electrode that is connected to the drain electrode; and
a pair of ohmic contacts that are formed between the semiconductor and the source electrode and between the semiconductor and the drain electrode and that have a second interval smaller than the first interval and are opposite to each other.

21. The thin film transistor array panel of claim 20, wherein the semiconductor has substantially the same plane shape as the second signal line except at an exposed portion between the source electrode and the drain electrode; and
further wherein the semiconductor has a larger width than the second signal line.

22. A thin film transistor array panel, comprising:
a substrate;
first and second signal lines that intersect on the substrate;
a gate electrode that is connected to the first signal line;
a source electrode that is connected to the second signal line;
a drain electrode that is opposite to the source electrode;
a pixel electrode that is connected to the drain electrode;
a semiconductor that includes an exposed portion between the source electrode and the drain electrode; and
an ohmic contact that is formed on the semiconductor and that includes a projection that is not covered with the source electrode and the drain electrode.

23. The thin film transistor array panel of claim 22, wherein the semiconductor has substantially the same plane shape as the second signal line except at the exposed portion between the source electrode and the drain electrode, and further wherein the semiconductor has a larger width than the second signal line.

24. The thin film transistor array panel of claim 22, wherein the semiconductor comprises:
a first portion that is covered with the second signal line and the drain electrode; and
a second portion that is not covered with the second signal line and the drain electrode;
wherein the second portion includes:
a third portion that is positioned between the source electrode and the drain electrode, and
a fourth portion that is positioned in an area except a portion between the source electrode and the drain electrode.
